(19) United States
(12) Patent Application Publication
(10) Pub. No.: US 2025/0203922 A1
(43) Pub. Date: Jun. 19, 2025

(54) SEMICONDUCTOR DEVICE

(71) Applicant: Renesas Electronics Corporation, Tokyo (JP)

(72) Inventors: Tatsuyoshi UENO, Tokyo (JP); Yuji ISHII, Tokyo (JP)

(21) Appl. No.: 18/931,214

(22) Filed: Oct. 30, 2024

(30) Foreign Application Priority Data
Dec. 18, 2023 (JP) 2023-213250

(51) Int. Cl. H01L 29/78; H01L 29/06; H01L 29/08

(52) U.S. Cl. CPC H10D 30/65; H10D 62/102; H10D 62/157

(57) ABSTRACT

A semiconductor device includes a semiconductor substrate, a first semiconductor region formed in the semiconductor substrate, a buried region formed in the semiconductor substrate, a second semiconductor region disposed over the buried region, a third semiconductor region disposed over the buried region, a drain region formed in the second semiconductor region, a source region formed in the third semiconductor region, and a gate electrode layer formed on an upper surface of the semiconductor substrate. The first semiconductor region includes a first region formed between the third semiconductor region and the buried region, and a second region formed between the second semiconductor region and the buried region. The semiconductor substrate, the first semiconductor region, and the second semiconductor region each have a first conductivity type. The buried region and the third semiconductor region each have a second conductivity type opposite the first conductivity type.

### CROSS-REFERENCE TO RELATED APPLICATIONS

The disclosure of Japanese Patent Application No. 2023-213250 filed on Dec. 18, 2023, including the specification, drawings and abstract is incorporated herein by reference in its entirety.

### BACKGROUND

The present disclosure relates to semiconductor devices, particularly to semiconductor devices including Laterally Diffused Metal Oxide Semiconductor (LDMOS) transistors.

LDMOS transistors have a structure that the drain region laterally extends to mitigate the electric field strength between the drain and the gate. Therefore, LDMOS transistors, having high breakdown voltage, are used in automobiles, motor drives, audio amplifiers, and the like.

There are disclosed techniques listed below.
[Patent Document 1] Japanese Unexamined Patent Application Publication No. 2019-046911

Patent Document 1 discloses an LDMOS transistor that includes a second conductivity type impurity region separating the buried region and the body region, both of which have a first conductivity type. By providing this impurity region, it is possible to mitigate the vertical (depth direction) electric field of the drain region when a high voltage is applied to the drain and back gate, thereby improving the breakdown voltage.

### SUMMARY

As the device size of LDMOS transistors is reduced, further high breakdown voltage is required. Other problems and novel features will become apparent from the description of this specification and the accompanying drawings.

In the present disclosure, the semiconductor device includes a semiconductor substrate having an upper surface; a first semiconductor region formed in the semiconductor substrate; a buried region formed in the semiconductor substrate or in the first semiconductor region; a second semiconductor region formed in the first semiconductor region and disposed over the buried region; a third semiconductor region formed in the first semiconductor region and disposed over the buried region; a drain region formed in the second semiconductor region; a source region formed in the third semiconductor region; and a gate electrode layer formed on the upper surface of the semiconductor substrate. The first semiconductor region has a first region formed between the third semiconductor region and the buried region in a direction perpendicular to the upper surface of the semiconductor substrate, and a second region formed between the second semiconductor region and the buried region in a direction perpendicular to the upper surface of the semiconductor substrate. The semiconductor substrate, the first semiconductor region, and the second semiconductor region each have a first conductivity type. The buried region and the third semiconductor region each have a second conductivity type opposite the first conductivity type. An impurity concentration of the first region and an impurity concentration of the second region are higher than an impurity concentration of the first semiconductor region.

The present disclosure provides a semiconductor device that enables further high breakdown voltage.

### BRIEF DESCRIPTION OF THE DRAWINGS

FIG. 1 is a cross-sectional view of a semiconductor device of the present disclosure.

FIG. 2 is a cross-sectional view of the semiconductor device of the present disclosure.

FIG. 3 is a cross-sectional view of the semiconductor device of the present disclosure.

FIG. 4 is a cross-sectional view of a comparative example of the semiconductor device.

FIG. 5A is a diagram showing the concentration distribution of impact ions in the semiconductor device.

FIG. 5B is a diagram showing the concentration distribution of impact ions in the semiconductor device.

FIG. 6 is a diagram showing the distribution of electric field strength in the semiconductor device.

FIG. 7 is a diagram showing the correlation between the breakdown voltage in the OFF state of the semiconductor device and the impurity doping amount in the second region.

FIG. 8 is a diagram showing the correlation between the breakdown voltage in the OFF state of the semiconductor device and the width of the Shallow Trench Isolation (STI) in the channel length direction.

FIG. 9 is a diagram showing the correlation between the normalized ON-resistance and the width of the STI in the channel length direction.

FIG. 10 is a cross-sectional view of a semiconductor device according to the present disclosure.

FIG. 11 is a cross-sectional view of a semiconductor device according to the present disclosure.

### DETAILED DESCRIPTION

Hereinafter, embodiments of the present disclosure will be described in detail with reference to the drawings. In the specification and drawings, the same or corresponding components are designated by the same reference numerals, and redundant description is omitted. In the drawings, components may be omitted or simplified for convenience of explanation. Also, at least some of the embodiments may be arbitrarily combined with each other.

In the semiconductor device according to the present disclosure, a conductivity type (p-type or n-type) of a semiconductor substrate, a semiconductor region, a diffusion region, a transistor, etc., may be inverted. Therefore, if one conductivity type is designated as a first conductivity type and the other conductivity type as a second conductivity type, the first conductivity type may be p-type and the second conductivity type may be n-type, or the first conductivity type may be n-type and the second conductivity type may be p-type.

The impurity concentration of components included in the semiconductor device according to the present disclosure refers to the peak value in the measured region of the component. Furthermore, when comparing the impurity concentrations of two components and stating “the same level”, it does not mean they are perfectly identical. Even if the impurity concentrations of two components differ due to manufacturing variations, if the set values of the impurity concentrations of the two components are the same, the impurity concentrations of the two components are considered to be the same.

### First Embodiment

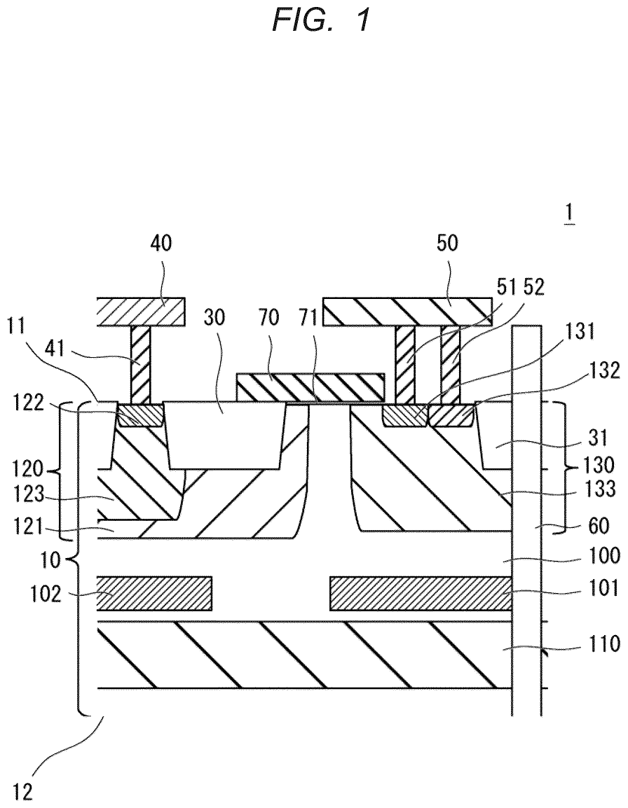

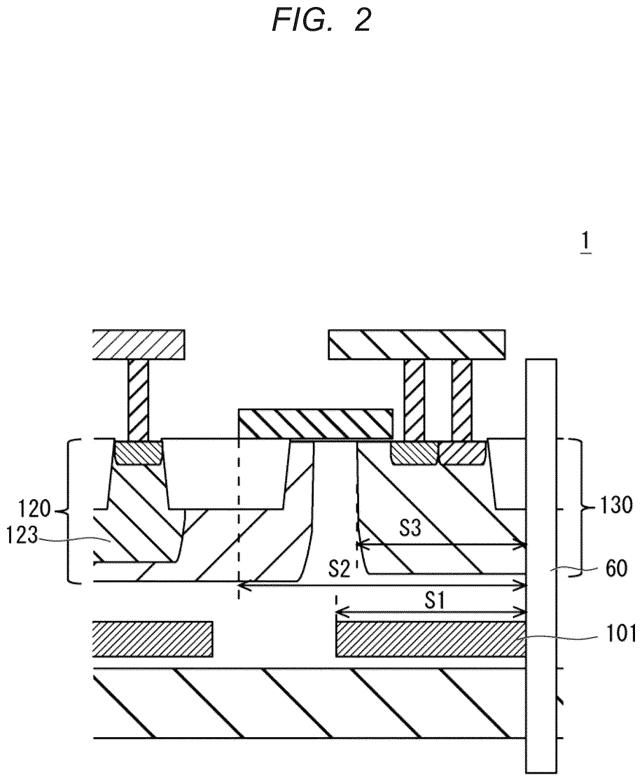

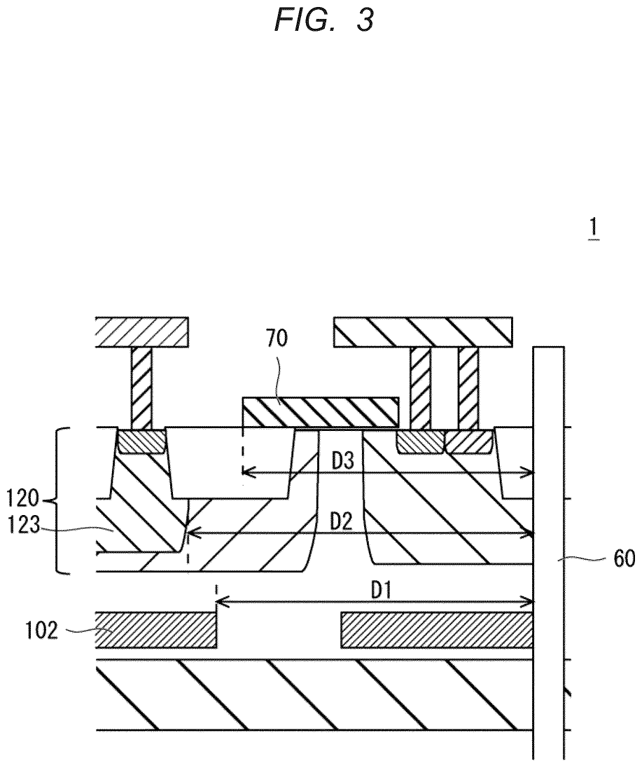

FIG. 1 is a cross-sectional view of a semiconductor device 1, and the semiconductor device 1 includes a semiconductor substrate 10 having a first conductivity type, and a plurality of regions formed in or on the semiconductor substrate 10. FIGS. 2 and 3 are diagrams for explaining the positional relationship of the plurality of regions, respectively, where the components shown are the same as in FIG. 1, and some reference numerals are omitted.

Examples of the semiconductor device 1 include a semiconductor chip including an LDMOS transistor, a semiconductor wafer, and a package in which these are mounted internally. FIG. 1 shows a cross-sectional view in the channel length direction of the LDMOS transistor.

The semiconductor substrate 10 has an upper surface 11 and a lower surface 12. Unless otherwise specified, the components included in the semiconductor device 1 shown in FIG. 1 are formed on the upper surface 11 side of the semiconductor substrate 10. The semiconductor substrate 10 may be a laminate including a substrate body and an epitaxial layer formed on the substrate body. This epitaxial layer corresponds to a first semiconductor region 100 described later.

A buried region 110 having a second conductivity type opposite the first conductivity type is formed in the semiconductor substrate 10. For example, the buried region 110 is formed by introducing impurities indicating the second conductivity type into the semiconductor substrate 10. If the semiconductor substrate 10 is a laminate including a substrate body and an epitaxial layer, the buried region 110 may be formed in the epitaxial layer.

The buried region 110 may be formed over the entire surface of the semiconductor substrate 10 or may be partially formed using a mask. Furthermore, the method of forming the buried region 110 is an example and is not limited to this method.

The epitaxial layer included in the semiconductor substrate 10 is defined as the first semiconductor region 100 in this disclosure. The first semiconductor region 100 and the buried region 110 are formed by any of the above methods, therefore, the first semiconductor region 100 is formed on the buried region 110 or includes the buried region 110.

Furthermore, the first semiconductor region 100 has the same first conductivity type as the semiconductor substrate 10. It is preferable that the impurity concentration of the first semiconductor region 100 is approximately equal to or higher than that of the semiconductor substrate 10, and lower than that of the buried region 110.

A second semiconductor region 120 is disposed over the buried region 110 in the first semiconductor region 100. The second semiconductor region 120 has the first conductivity type, and it is preferable that the impurity concentration of the second semiconductor region 120 is higher than the impurity concentration of the first semiconductor region 100.

In the second semiconductor region 120, a drift region 121 of the first conductivity type, a drain region 122 of the first conductivity type, and a well region 123 of the first conductivity type are formed. The drift region 121 is formed in the second semiconductor region 120 to expand towards a third semiconductor region 130. It is preferable that the impurity concentration of the drift region 121 is lower than the impurity concentration of the well region 123. The impurity concentration of the drain region 122 is preferably higher than the impurity concentration of the well region 123. The well region 123 is positioned under the drain region 122, and the width of the well region 123 is smaller than the width of the drift region 121.

The drain region 122 is formed at the upper surface 11 of the semiconductor substrate 10. Furthermore, a conductive layer 41 is formed on the drain region 122, and a drain electrode layer 40 is formed on the conductive layer 41. The drain region 122 is electrically connected to the drain electrode layer 40 via the conductive layer 41.

The third semiconductor region 130 is disposed over the buried region 110 in the first semiconductor region 100. The third semiconductor region 130 has the second conductivity type, and it is preferable that the impurity concentration of the third semiconductor region 130 is higher than the impurity concentration of the first semiconductor region 100.

In the third semiconductor region 130, a source region 131 of the first conductivity type, a contact region 132 of the second conductivity type, and a well region 133 of the second conductivity type are formed. The impurity concentrations of the source region 131 and the contact region 132 are preferably higher than the impurity concentration of the well region 133. Furthermore, it is preferable that the impurity concentrations of the source region 131 and the contact region 132 are approximately the same.

The source region 131 and the contact region 132 are each disposed at the upper surface 11 of the semiconductor substrate 10. A conductive layer 51 is formed on the source region 131, and a conductive layer 52 is formed on the contact region 132. Furthermore, a source electrode layer 50 is formed on the conductive layer 51 and the conductive layer 52. The source region 131 and the contact region 132 are connected to the source electrode layer 50 via the conductive layer 51 and the conductive layer 52.

In the cross-sectional view shown in FIG. 1, the second semiconductor region 120 and the third semiconductor region 130 are spaced apart from each other in the direction along the upper surface 11 of the semiconductor substrate 10.

A first element isolation insulating layer 30 and a first element isolation insulating layer 31 are STI (Shallow Trench Isolation), having a function to prevent leakage between the gate and the drain, or between the gate and the source. The first element isolation insulating layer 30 is formed in the second semiconductor region 120, more specifically, in the drift region 121, and at the upper surface 11 of the semiconductor substrate 10. Furthermore, the first element isolation insulating layer 30 is disposed between the drain region 122 and the source region 131. The first element isolation insulating layer 31 is formed in the third semiconductor region 130, and at the upper surface 11 of the semiconductor substrate 10.

A second element isolation insulating layer 60 is DTI (Deep Trench Isolation), having a function to prevent leakage between adjacent transistors. The second element isolation insulating layer 60 penetrates through the first element isolation insulating layer 31, the third semiconductor region 130, the first semiconductor region 100, and the buried region 110. Although not shown, the second element isolation insulating layer 60 is formed to surround the LDMOS transistor in plan view.

Furthermore, the semiconductor device 1 includes a gate electrode layer 70 formed on the semiconductor substrate 10 via a gate insulating layer 71. The gate electrode layer 70 is disposed on the upper surface of the semiconductor substrate, between the drain region 122 and the source region 131, along the direction of the upper surface of the semiconductor substrate 10. In other words, in plan view, the gate electrode layer is disposed between the drain region 122 and the source region 131. Also, the gate electrode layer 70 and the gate insulating layer 71 are formed on the upper surface 11 of the semiconductor substrate 10.

It is preferable that the gate electrode layer 70 is formed to overlap a part of the first element isolation insulating layer 30, a part of the second semiconductor region 120, and a part of the third semiconductor region 130. The gate insulating layer 71 is disposed between the gate electrode layer 70 and the semiconductor substrate 10.

The gate electrode layer 70 is disposed on the upper surface 11 of the semiconductor substrate 10 and on the first element isolation insulating layer 30. Also, the end portion of the gate electrode layer 70 facing the drain region 122 is disposed on the first element isolation insulating layer 30.

When the gate electrode layer 70 is formed to overlap a part of the first element isolation insulating layer 30, the first element isolation insulating layer 30 isolates between the gate electrode layer 70 and the second semiconductor region 120. Therefore, the gate insulating layer 71 is not disposed between the gate electrode layer 70 and the first element isolation insulating layer 30.

The semiconductor device 1 has a first region 101 and a second region 102 in the first semiconductor region 100, both having a first conductivity type. The impurity concentration of the first region 101 and the impurity concentration of the second region 102 are higher than the impurity concentration of the first semiconductor region 100, respectively. Furthermore, it is preferable that the impurity concentration of the second region 102 is approximately equal to or less than the impurity concentration of the first region 101.

The first region 101 is, in the cross-sectional view shown in FIG. 1, disposed under the third semiconductor region 130. It is preferable that an end portion of the first region 101 facing the second region 102 is aligned with, or extends further towards, the drain region 122 than an end portion of the third semiconductor region 130 facing the second semiconductor region 120. Furthermore, it is preferable that an end portion of the first region 101 facing the second element isolation insulating layer 60 is in contact with the side surface of the second element isolation insulating layer 60. Such a shape is obtained by forming the second element isolation insulating layer 60 after forming the first region 101.

FIG. 2 is a diagram for explaining the positional relationship between the first region 101 and other regions. It is preferable that a first distance (S1) between an end portion of the first region 101 facing the second region 102 and the side surface of the second element isolation insulating layer 60 is equal to or less than a second distance (S2) between an end portion of the gate electrode layer 70 facing the drain region 122 and the side surface of the second element isolation insulating layer 60. Furthermore, it is preferable that the first distance (S1) is equal to or greater than a third distance (S3) between an end portion of the third semiconductor region 130 facing the second semiconductor region 120 and the side surface of the second element isolation insulating layer 60.

Moreover, in plan view, an end portion of the first region 101 facing the second region 102 is positioned between the second semiconductor region 120 and the third semiconductor region 130. Furthermore, in plan view, the well region 123 is included in the first region 101.

The first region 101 is separated from the buried region 110 in a direction perpendicular to the upper surface 11 of the semiconductor substrate 10. Moreover, it is preferable that the first region 101 is separated from the second semiconductor region 120 and the third semiconductor region 130, but the upper surface of the first region 101 may be in contact with the bottom part of the second semiconductor region 120 and the bottom part of the third semiconductor region 130.

The second region 102 is, in the cross-sectional view shown in FIG. 1, disposed under the second semiconductor region 120. In plan view, an end portion of the second semiconductor region 120 facing the first region 101 is positioned between the end portion of the first region 101 facing the second region 102 and the second element isolation insulating layer 60.

FIG. 3 is a diagram for explaining the positional relationship between the second region 102 and other regions. It is preferable that a first distance (D1) between an end portion of the second region 102 facing the first region 101 and the side surface of the second element isolation insulating layer 60 is equal to or less than a second distance (D2) between an end portion of the well region 123 of the second semiconductor region 120 facing the third semiconductor region 130 and the second element isolation insulating layer 60. Furthermore, it is preferable that the first distance (D1) is equal to or greater than a third distance (D3) between an end portion of the gate electrode layer 70 facing the drain region 122 and the side part of the second element isolation insulating layer 60.

Moreover, in plan view, an end portion of the second region 102 facing the first region 101 is positioned between the well region 123 of the second semiconductor region 120 and an end portion of the gate electrode layer 70 facing the drain region 122.

The second region 102 is separated from the buried region 110 in a direction perpendicular to the upper surface 11 of the semiconductor substrate 10. Furthermore, it is preferable that the second region 102 is separated from the second semiconductor region 120, but the upper surface of the second region 102 may be in contact with the bottom part of the second semiconductor region 120.

By adopting such a configuration, it is possible to provide a semiconductor device that can further alleviate the electric field strength at the bottom of the well region 123 and the electric field strength between the drain and the gate, thereby enabling further enhancement of the breakdown voltage.

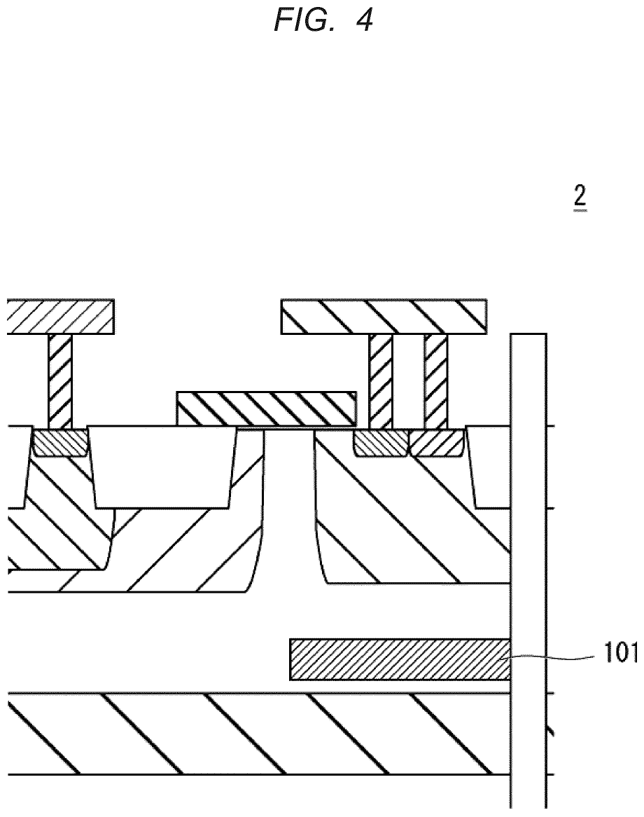

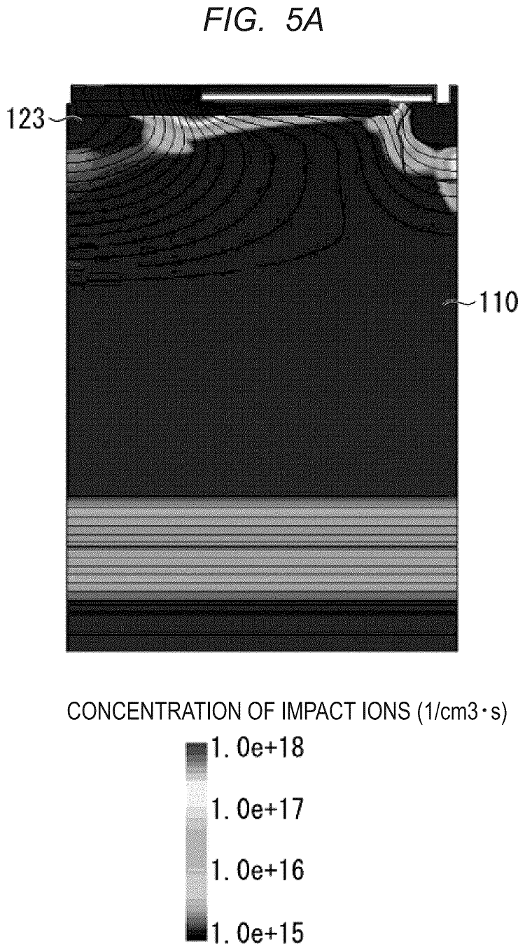

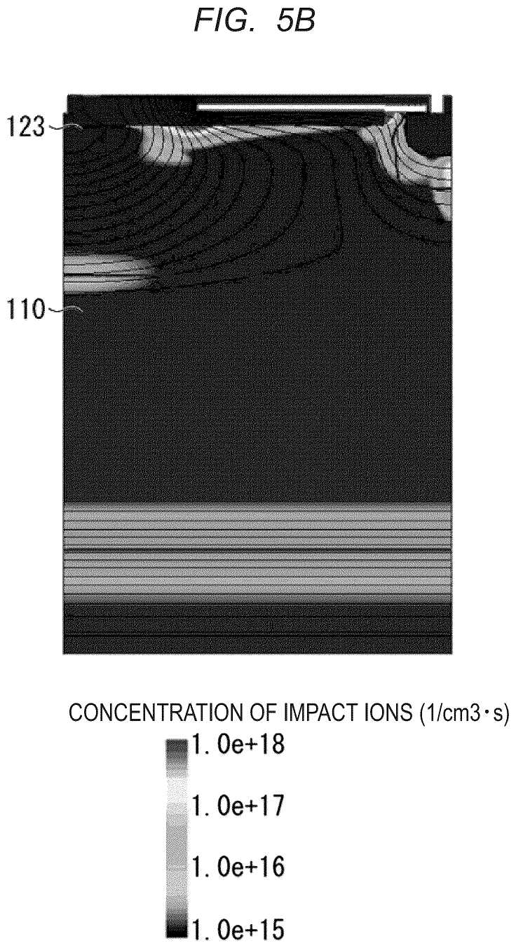

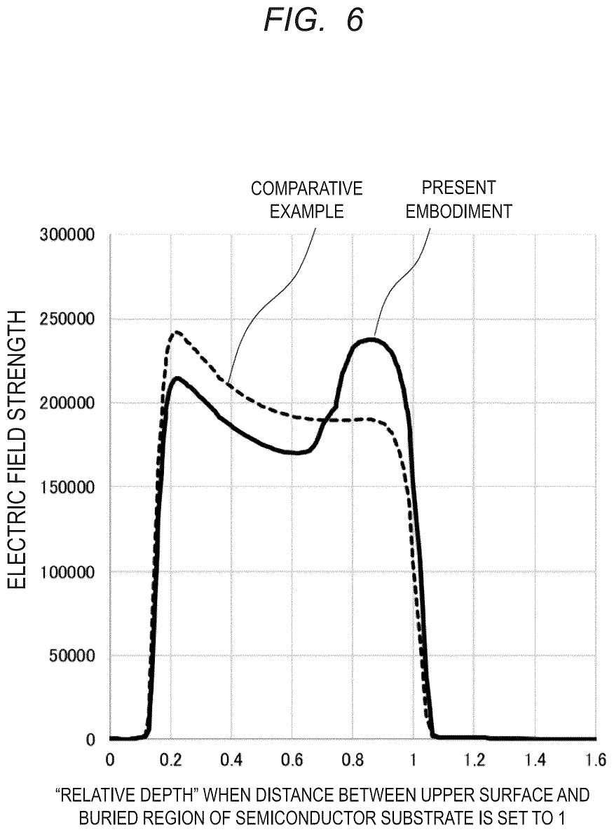

FIG. 4 is a cross-sectional view of a semiconductor device 2, which is a comparative example, without the second region 102. FIG. 5A and FIG. 5B show the simulation results of the concentration distribution of impact ions in the semiconductor device 1 and the semiconductor device 2. FIG. 6 shows the simulation results of the electric field strength in the semiconductor device 1 and the semiconductor device 2.

FIG. 5A shows simulation results of the concentration distribution of impact ions when a gate voltage Vg of 0 V, a drain voltage Vd, and a back gate voltage Vbg of −100 V are applied in the semiconductor device 2, which is a comparative example. FIG. 5B shows simulation results of the concentration distribution of impact ions when the same voltages as applied to the semiconductor device 2 are applied to the semiconductor device 1.

In the semiconductor device 2, which is a comparative example, it is understood that impact ions are concentrated directly below the well region 123 of the second semiconductor region 120. On the other hand, in the semiconductor device 1, it is understood that impact ions are not concentrated directly below the well region 123 but are dispersed near the buried region 110.

FIG. 6 shows a plot indicating simulation results of electric field strength in the semiconductor device 1 and the semiconductor device 2 against the depth (hereinafter referred to as “relative depth”) when the distance between the upper surface 11 and the buried region 110 of the semiconductor substrate 10 is set to 1. The electric field strengths of the semiconductor device 1 and the semiconductor device 2 when the same voltages as in FIG. 5A and FIG. 5B are applied are shown respectively.

Near the relative depth of 0.2, that is, in the region close to the upper surface 11, it is understood that the electric field strength of the semiconductor device 2 is higher than the electric field strength of the semiconductor device 1. Furthermore, near the relative depth of 0.9, that is, in the region close to the buried region 110, it is understood that the electric field strength of the semiconductor device 1 is higher than the electric field strength of the semiconductor device 2.

From the above, by forming the second region 102, it is possible to alleviate the electric field directly below the well region 123 of the second semiconductor region 120, thereby obtaining a high-breakdown-voltage LDMOS transistor.

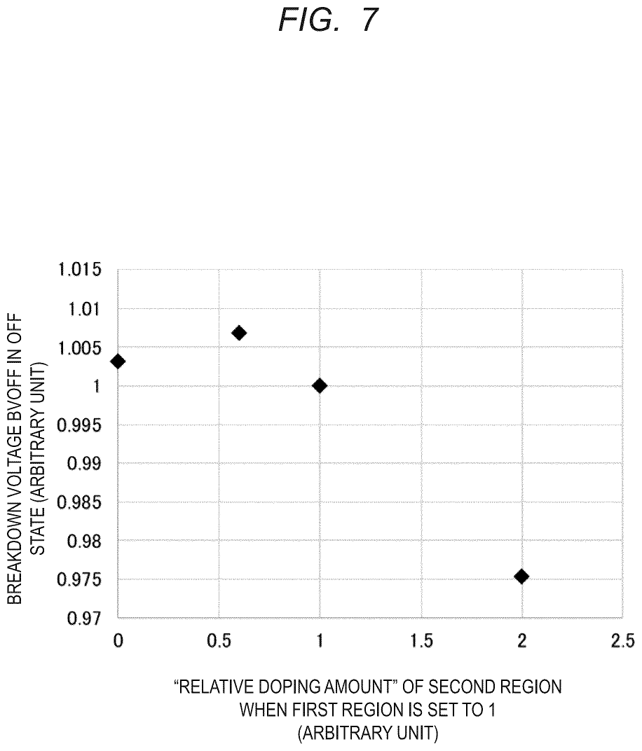

Next, the correlation between the breakdown voltage in the OFF state of the semiconductor device 1 and the impurity doping amount of the second region 102 will be explained using FIG. 7. FIG. 7 shows a plot of the simulation results of the breakdown voltage BVoff in the OFF state of the semiconductor device 1 and the impurity doping amount of the second region 102 (hereinafter referred to as “relative doping amount”) when the impurity doping amount of the first region 101 is set to 1.

At a relative doping amount of the second region 102 of around 0.6, it was confirmed that the condition for the breakdown voltage BVoff in the OFF state of the semiconductor device 1 to be greater than 1 is met. Therefore, it is understood that further increasing the breakdown voltage of the semiconductor device 1 is possible by reducing the impurity concentration of the second region 102 below the impurity concentration of the first region 101.

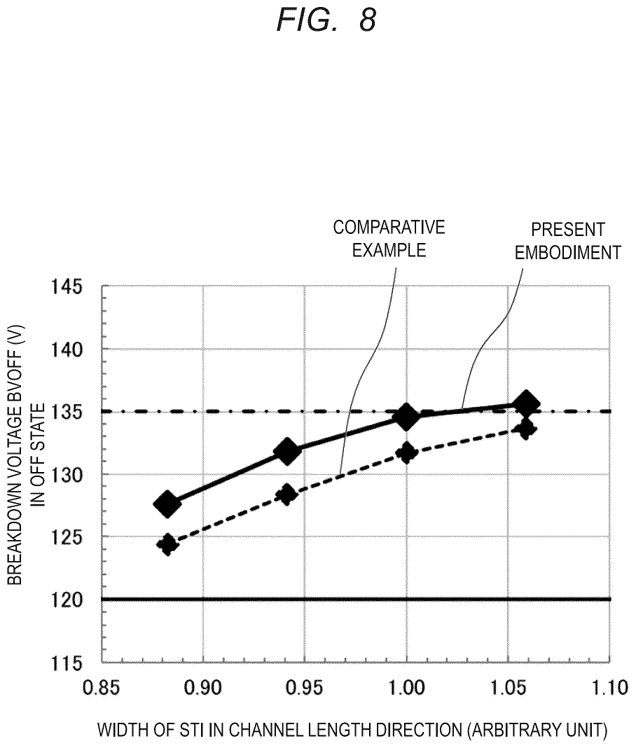

FIG. 8 shows a plot of measured data of the breakdown voltage BVoff in the OFF state of the semiconductor device 1 and the semiconductor device 2. The horizontal axis of the plot shown in FIG. 8 represents the relative width, which is normalized to 1 when the width of the first element isolation insulating layer 30 in the channel length direction achieves a breakdown voltage BVoff of 135 V in the OFF state of the semiconductor device 1. The vertical axis of the plot shown in FIG. 8 represents the breakdown voltage BVoff in the OFF state of the semiconductor device 1 and the semiconductor device 2.

The breakdown voltage BVoff in the OFF state of the semiconductor device 1 is improved by about 3 V compared to the breakdown voltage BVoff in the OFF state of the semiconductor device 2, which is a comparative example. Furthermore, it was found that by the configuration of the semiconductor device 1, an LDMOS transistor having an OFF-state breakdown voltage BVoff of 135 V or more can be obtained.

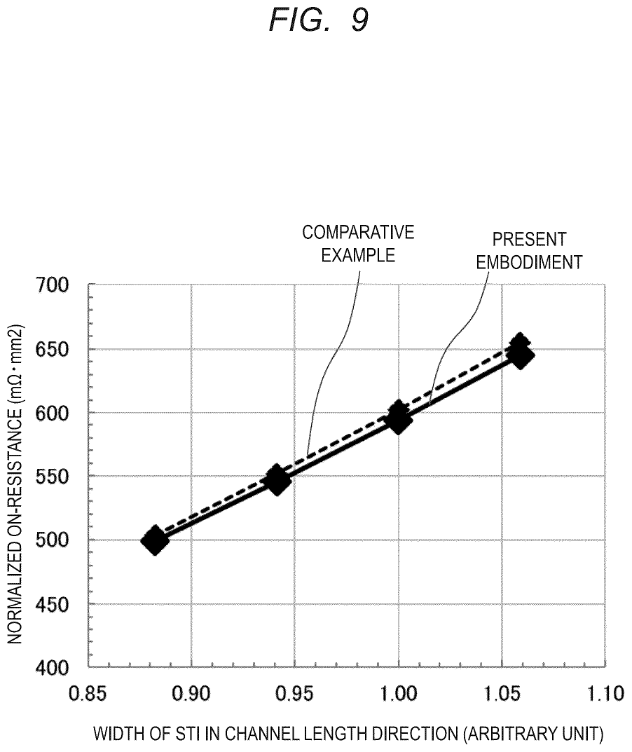

FIG. 9 shows a plot of measured data of normalized ON-resistance Rsp, where the horizontal axis indicates the relative width of the first element isolation insulating layer 30 in the channel length direction, and the vertical axis indicates the normalized ON-resistance Rsp.

For example, referring to FIG. 8, the relative width of the first element isolation insulating layer 30 in the channel length direction, in the case where the semiconductor device 2, which is a comparative example, can achieve an OFF-state breakdown voltage BVoff of 135 V, is predicted to be about 1.10. Extrapolating the plot of the comparative example in FIG. 9 to the point where the relative width is 1.10, the value of the normalized ON-resistance Rsp is predicted to be about 708 mΩ·mm².

On the other hand, since the relative width of the first element isolation insulating layer 30 in the channel length direction is 1 in the case where the semiconductor device 1 can achieve an OFF-state breakdown voltage BVoff of 135 V, the normalized ON-resistance Rsp is about 594 mΩ·mm². Therefore, it was found that the normalized ON-resistance Rsp at the relative width capable of achieving the 135 V OFF-state breakdown voltage BVoff of the LDMOS transistor can be reduced by about 16.1%.

### Second Embodiment

In the second embodiment, a modified example of the semiconductor device 1 according to the first embodiment is described. The description of configurations similar to those in the first embodiment is omitted.

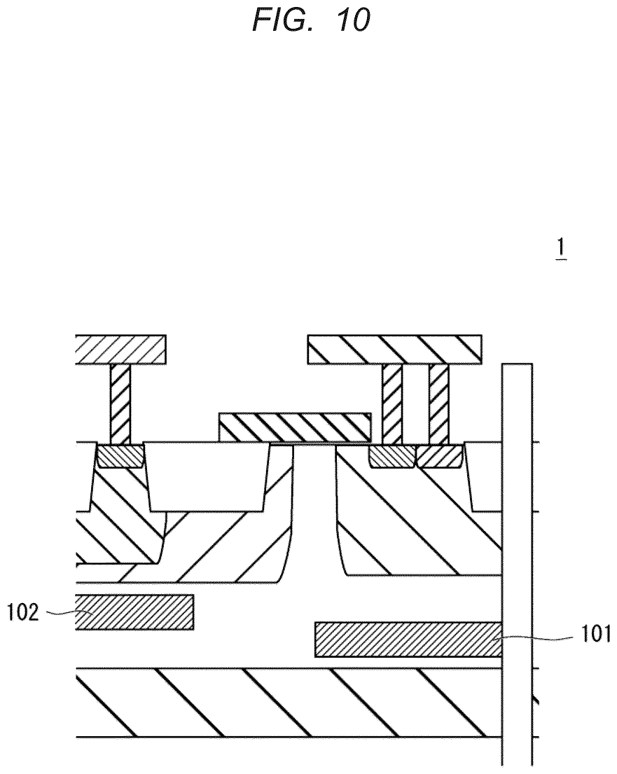

The semiconductor device 1 shown in FIG. 10 illustrates a case where the first region 101 and the second region 102 are formed at different depths. The first region 101 and the second region 102 may be formed using different masks, or by changing the impurity introduction conditions for each other. In FIG. 10, although the first region 101 is formed at a deeper position than the second region 102, the second region 102 may be formed at a deeper position than the first region 101. Also, when the upper surface 11 of the semiconductor substrate 10 is used as a reference surface, the formation position of the first region 101 may be shallower than the formation position of the second region 102.

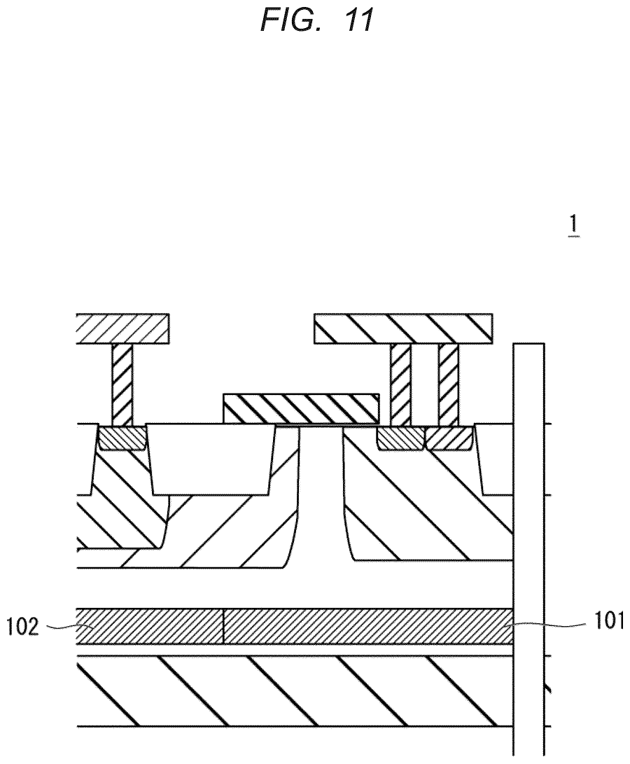

The semiconductor device 1 shown in FIG. 11 illustrates a case where the end portion of the first region 101 and the end portion of the second region 102 are in contact with each other. When impurities diffuse laterally by heat treatment after impurity introduction, the first region 101 and the second region 102 may come into contact with each other.

The semiconductor device 1 according to the present embodiment preferably has the first region 101 and the second region 102 separated from each other. However, if the impurity concentration 41 the first region 101 and the impurity concentration of the second region 102 have a gradient, an effect according to the configuration of the semiconductor device 1 of the second embodiment can be obtained as long as the area indicating the peak value of the impurity concentration of the first region 101 and the area indicating the peak value of the impurity concentration of the second region 102 are separated from each other.

As described above, the invention made by the present inventors has been concretely described based on the embodiments. However, it goes without saying that various modifications can be made without departing from the gist of the disclosed embodiments.

What is claimed is:

1. A semiconductor device comprising:
a semiconductor substrate having an upper surface;
a first semiconductor region formed in the semiconductor substrate;
a buried region formed in the semiconductor substrate or in the first semiconductor region;
a second semiconductor region formed in the first semiconductor region and disposed over the buried region;
a third semiconductor region formed in the first semiconductor region and disposed over the buried region;
a drain region formed in the second semiconductor region;
a source region formed in the third semiconductor region; and
a gate electrode layer formed on the upper surface of the semiconductor substrate,
wherein the first semiconductor region comprises:
a first region formed between the third semiconductor region and the buried region in a direction perpendicular to the upper surface of the semiconductor substrate; and
a second region formed between the second semiconductor region and the buried region in a direction perpendicular to the upper surface of the semiconductor substrate,
wherein the semiconductor substrate, the first semiconductor region, and the second semiconductor region each have a first conductivity type,
wherein the buried region and the third semiconductor region each have a second conductivity type opposite the first conductivity type, and
wherein an impurity concentration of the first region and an impurity concentration of the second region are higher than an impurity concentration of the first semiconductor region.

2. The semiconductor device according to claim 1,
wherein the impurity concentration of the second region is equal to or less than the impurity concentration of the first region.

3. The semiconductor device according to claim 1,
wherein, when the upper surface of the semiconductor substrate is taken as a reference surface, a depth of the first region and a depth of the second region are different from each other.

4. The semiconductor device according to claim 1,
wherein, when the upper surface of the semiconductor substrate is taken as a reference surface, a formation position of the first region is shallower than a formation position of the second region.

5. The semiconductor device according to claim 1,
wherein the first region is separated from the second direction along the upper surface of the region in a semiconductor substrate.

6. The semiconductor device according to claim 1,
wherein the second semiconductor region comprises the drain region, a drift region, and a well region having the first conductivity type,
wherein the well region is disposed under the drain region,
wherein, in plan view, the well region is included in the first region,
wherein an impurity concentration of the drift region is lower than an impurity concentration of the well region, and
wherein the impurity concentration of the drain region is higher than the impurity concentration of the well region.

7. The semiconductor device according to claim 6,
wherein, in plan view, an end portion of the first region facing the second region is positioned between an end portion of the gate electrode layer facing the drain region and the third semiconductor region.

8. The semiconductor device according to claim 6,
wherein, in plain view, an end portion of the second region facing the first region is positioned between the well region and the end portion of the gate electrode layer facing the drain region.

9. The semiconductor device according to claim 6, further comprising:
a first element isolation insulating layer formed in the second semiconductor region and at the upper surface of the semiconductor substrate; and
a second element isolation insulating layer formed to penetrate through the third semiconductor region, the first semiconductor region, and the buried region,
wherein, when the upper surface of the semiconductor substrate is taken as a reference surface, a depth of the second element isolation insulating layer is greater than a depth of the first element isolation insulating layer.

10. The semiconductor device according to claim 9,
wherein the first element isolation insulating layer is formed in the drift region.

11. The semiconductor device according to claim 9,
wherein the first region is in contact with a side surface of the second element isolation insulating layer.

12. The semiconductor device according to claim 9,
wherein a first distance between the end portion of the first region facing the second region and the side surface of the second element isolation insulating layer is equal to or less than a second distance between the end portion of the gate electrode layer facing the drain region and the side surface of the second element isolation insulating layer, and is equal to or greater than a third distance between the end portion of the third semiconductor region facing the second semiconductor region and the side surface of the second element isolation insulating layer.

13. The semiconductor device according to claim 9,
wherein a first distance between the end portion of the second region facing the first region and the side surface of the second element isolation insulating layer is equal to or less than a second distance between the end portion of the well region facing the third semiconductor region and the side surface of the second element isolation insulating layer, and is equal to or greater than a third distance between the end portion of the gate electrode layer facing the drain region and the side surface of the second element isolation insulating layer.
